(19) United States
(12) Patent Application Publication
(10) Pub. No.: US 2011/0127515 A1
(43) Pub. Date: Jun. 2, 2011

(54) PHOTOELECTRIC CONVERSION ELEMENT

(75) Inventors: Kunihito Miyake, Tsukuba-shi (JP); Takanobu Noguchi, Tsukuba-shi (JP)

(73) Assignee: SUMITOMO CHEMICAL COMPANY, LIMITED, Chuo-ku, Tokyo (JP)

(21) Appl. No.: 13/056,065

(22) PCT Filed: Aug. 5, 2009
(86) PCT No.: PCT/JP2009/064214

§ 371 Date: Jan. 26, 2011

(30) Foreign Application Priority Data
Aug. 6, 2008 (JP) 2008-202715

(51) Int. Cl. H01L 51/42; C08F 28/06

(52) U.S. Cl. 257/40; 526/257; 526/259; 257/E51.001

(57) ABSTRACT

Disclosed is a photoelectric conversion element comprising a pair of electrodes, at least one of which is transparent or translucent, and a photoactive layer provided between the electrodes, wherein the photoactive layer contains an electron donating compound and an electron accepting compound, and the electron donating compound or the electron accepting compound is a polymer compound having a repeating unit represented by the following formula (I), and the proportion of the repeating unit represented by the formula (I) is the highest among all of the repeating units contained in the polymer compound:

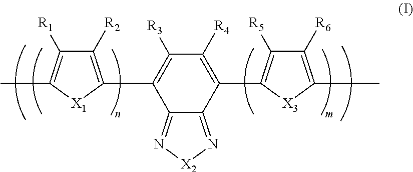

wherein R₁, R₂, R₃, R₄, R₅ and R₆ are the same or different, represent a hydrogen atom or a substituent, and may be linked with one another to form a cyclic structure; X₁, X₂ and X₃ are the same or different and represent a sulfur atom, an oxygen atom, a selenium atom, —N(R₇)— or —CR₈═CR₉—; R₇, R₈, and R₉ are the same or different and represent a hydrogen atom or a substituent; and n and m are the same or different and represent an integer of 0 to 5; and when a plurality of R₁s, R₂s, R₅s, R₆s, X₁s or X₃s respectively exist, they may be the same or different.

### TECHNICAL FIELD

The present invention relates to a photoelectric conversion element comprising a photoactive layer containing a specific polymer compound.

### BACKGROUND ART

In recent years, it is required to reduce quantities of carbon dioxide released into the atmosphere for the prevention of global warming. For example, adoption of a solar system, in which a photoelectrochemical cell such as a silicon solar cell of a p-n junction type is used on the roof of a house, is proposed as a means promising for the reduction in CO₂. However, single crystals, polycrystals and amorphous silicon used in the above silicon photoelectrochemical cell have a problem that they are expensive because they require the conditions of high temperature and high vacuum in their production processes.

On the other hand, recently, organic thin film solar cells attract attention since high-temperature and high-vacuum processes can be omitted and there is a possibility that the solar cell can be fabricated at low cost by only an application process. As the organic thin film solar cells, an organic thin film solar cell comprising a photoactive layer composed of a conjugated polymer including repeating units (A) and repeating units (B) as an electron donating compound and an organic electron accepting compound (Applied Physics A79, 31-35 (2004)) is known. The molar ratio of the repeating units (A) and the repeating units (B) of the conjugated polymer is 0.36:0.33 (Advanced Material 15, 988 (2003)).

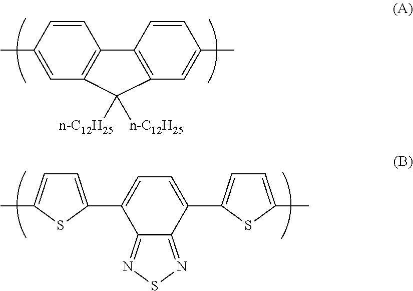

### DISCLOSURE OF THE INVENTION

However, the photoelectric conversion efficiency of the above-mentioned organic thin film solar cell is low and therefore further improvement in photoelectric conversion efficiency is required. It is an object of the present invention to provide a photoelectric conversion element having high photoelectric conversion efficiency.

The present invention provides, in its first aspect, a photoelectric conversion element comprising a pair of electrodes, at least one of which is transparent or translucent, and a photoactive layer provided between the electrodes, wherein the photoactive layer contains an electron donating compound and an electron accepting compound, and the electron donating compound or the electron accepting compound is a polymer compound having a repeating unit represented by the following formula (I), and the proportion of the repeating unit represented by the formula (I) is the highest among all of the repeating units contained in the polymer compound:

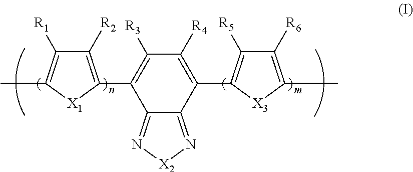

wherein R₁, R₂, R₃, R₄, R₅ and R₆ are the same or different, represent a hydrogen atom or a substituent, and may be linked with one another to form a cyclic structure; X₁, X₂ and X₃ are the same or different and represent a sulfur atom, an oxygen atom, a selenium atom, —N(R₇)— or —CR₈═CR₉—; R₇, R₈, and R₉ are the same or different and represent a hydrogen atom or a substituent; and n and m are the same or different and represent an integer of 0 to 5; and when a plurality of R₁s, R₂s, R₅s, R₆s, X₁s or X₃s respectively exist, they may be the same or different.

The present invention provides, in its second aspect, the photoelectric conversion element wherein n and m are an integer of 1 to 3.

The present invention provides, in its third aspect, the photoelectric conversion element wherein X₁, X₂ and X₃ are a sulfur atom, respectively.

The present invention provides, in its fourth aspect, the photoelectric conversion element wherein an amount of the repeating unit represented by the formula (I) is more than 50% of a total of all repeating units in the polymer compound.

The present invention provides, in its fifth aspect, the photoelectric conversion element wherein an amount of the repeating unit represented by the formula (I) is 52% or more of a total of all repeating units in the polymer compound.

The present invention provides, in its sixth aspect, the photoelectric conversion element wherein an amount of the repeating unit represented by the formula (I) is less than 100% of a total of all repeating units in the polymer compound.

The present invention provides, in its seventh aspect, the photoelectric conversion element wherein an amount of the repeating unit represented by the formula (I) is 98% or less of a total of all repeating units in the polymer compound.

The present invention provides, in its eighth aspect, the photoelectric conversion element wherein the polymer compound further includes a repeating unit represented by the formula (II):

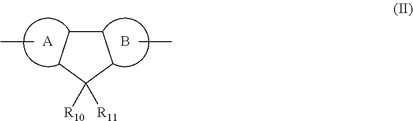

wherein a ring A and a ring B are the same or different and represent an aromatic ring. R₁₀ and R₁₁ are the same or different, and represent a hydrogen atom or a substituent, and may be linked with each other to form a cyclic structure.

The present invention provides, in its ninth aspect, the photoelectric conversion element wherein the proportion of the repeating units represented by the formula (II) is the second highest after the proportion of the repeating units represented by the formula (I) among all of the repeating units contained in the polymer compound.

The present invention provides, in its tenth aspect, the photoelectric conversion element wherein the repeating units in the polymer compound are only includes the repeating unit represented by the formula (I) and the repeating unit represented by the formula (II).

The present invention provides, in its eleventh aspect, the photoelectric conversion element wherein R₁, R₂, R₅ and R₆ are a hydrogen atom.

The present invention provides, in its twelfth aspect, the photoelectric conversion element wherein R₃ and R₄ are a hydrogen atom.

The present invention provides, in its thirteenth aspect, the photoelectric conversion element wherein R₁₀ and R₁₁ are a hydrocarbon group.

The present invention provides, in its fourteenth aspect, the photoelectric conversion element wherein R₁₀ and R₁₁ are an alkyl group.

The present invention provides, in its fifteenth aspect, the photoelectric conversion element wherein R₁₀ has 12 or more carbon atoms and R₁₁ has 12 or more carbon atoms.

The present invention provides, in its sixteenth aspect, the photoelectric conversion element wherein the ring A and the ring B are composed of from a five-membered ring to a ten-membered ring.

The present invention provides, in its seventeenth aspect, the photoelectric conversion element wherein the ring A and the ring B are a benzene ring or a naphthalene ring.

The present invention provides, in its eighteenth aspect, the photoelectric conversion element wherein an electron donating compound is the polymer compound having a repeating unit represented by the formula (I) and an electron accepting compound is a polymer compound having a thiophene structure.

The present invention provides, in its nineteenth aspect, the photoelectric conversion element wherein an electron accepting compound is the polymer compound having a repeating unit represented by the formula (I) and an electron donating compound is a polymer compound having a thiophene structure.

The present invention provides, in its twentieth aspect, the photoelectric conversion element wherein the polymer compound having a thiophene structure is a polythiophene homopolymer.

The present invention provides, in its twenty-first aspect, an image sensor including the photoelectric conversion element.

The present invention provides, in its twenty-second aspect, a polymer compound having a repeating unit represented by the following formula (I), and the proportion of the repeating unit represented by the formula (I) is the highest among all of the repeating units contained in the polymer compound:

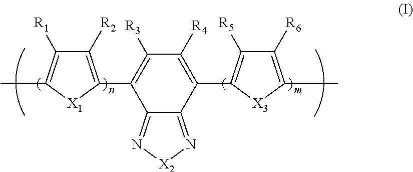

wherein R₁, R₂, R₃, R₄, R₅ and R₆ are the same or different and represent a hydrogen atom or a substituent, and may be linked with one another to form a cyclic structure; X₁, X₂ and X₃ are the same or different and represent a sulfur atom, an oxygen atom, a selenium atom, —N(R₇)— or —CR₆═CR₉—; R₇, R₈, and R₉ are the same or different and represent a hydrogen atom or a substituent; and n and m are the same or different and represent an integer of 0 to 5; and when a plurality of R₁s, R₂s, R₅s, R₆s, X₁s or X₃s respectively exist, they may be the same or different.

### MODE FOR CARRYING OUT THE INVENTION

Hereinafter, the present invention will be described in detail.

In the formula (I), n and m are the same or different and represent an integer of 0 to 5. The n and m are preferably an integer of 1 to 3, and more preferably 1.

R₁, R₂, R₃, R₄, R₅ and R₆ are the same or different, and represent a hydrogen atom or a substituent. When R₁ to R₆ are a substituent, the substituent preferably has 1 to 30 carbon atoms. Examples of the substituents include alkyl groups such as a methyl group, an ethyl group, a butyl group, a hexyl group, an octyl group and a dodecyl group; alkoxy groups such as a methoxy group, an ethoxy group, a butoxy group, a hexyloxy group, an octyloxy group and a dodecyloxy group; and aryl groups such as a phenyl group and a naphthyl group.

R₁, R₂, R₃, R₄, R₅ and R₆ may be linked with one another to form a cyclic structure.

Examples of the cyclic structures formed by the linkage of R₁ and R₂ and the linkage of R₅ and R₆ include the following cyclic structure.

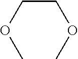

Examples of the cyclic structures formed by the linkage of R₃ and R₄ include the following cyclic structure:

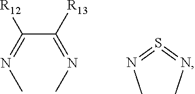

wherein R₁₂ and R₁₃ are the same or different, and represent a hydrogen atom or a substituent.

Examples of the substituents represented by R₁₂ and R₁₃ include the same groups as the substituents represented by R₁ to R₆ described above.

The R₁ to R₆ are preferably a hydrogen atom or alkyl groups, and more preferably a hydrogen atom.

X₁, X₂ and X₃ are the same or different and represent a sulfur atom, an oxygen atom, a selenium atom, —N(R₇)— or —CR₈═CR₉—. R₇, R₈ and R₉ are the same or different and represent a hydrogen atom or a substituent. When R₇, R₈ and R₉ are a substituent, examples of the substituents include alkyl groups such as a methyl group, an ethyl group, a butyl group, a hexyl group, an octyl group and a dodecyl group; and aryl groups such as a phenyl group and a naphthyl group.

X₁, X₂ and X₃ are preferably a sulfur atom, respectively.

The repeating unit represented by the formula (I) is preferably a repeating unit represented by the formula (I-1).

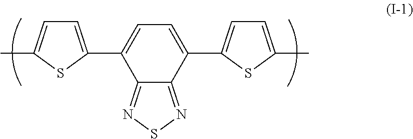

The polymer compound used in the present invention is a polymer compound having a repeating unit represented by the formula (I), wherein the content (molar number) of the repeating unit represented by the formula (I) is the highest among all of the repeating units in the polymer compound.

In the polymer compound used in the present invention, a polymer compound, in which an amount of the repeating unit represented by the formula (I) is more than 50% of a total of all repeating units in the polymer compound, is preferable. The photoelectric conversion element containing a polymer compound in which an amount of the repeating unit represented by the formula (I) is more than 50% has higher photoelectric conversion efficiency than that of the photoelectric conversion element using a polymer compound in which the repeating unit represented by the formula (I) is 50% or less. More preferably, an amount of the repeating units represented by the formula (I) is 52% or more of a total of all repeating units in the polymer compound. Furthermore preferably, an amount of the repeating units represented by the formula (I) is 55% or more of a total of all repeating units in the polymer compound.

An amount of the repeating unit represented by the formula (I) preferably is less than 100% of a total of all repeating units in the polymer compound. More preferably, an amount of the repeating unit represented by the formula (I) is 98% or less of a total of all repeating units in the polymer compound. Furthermore preferably, an amount of the repeating unit represented by the formula (I) is 70% or less of a total of all repeating units in the polymer compound. The polymer compound used in the present invention preferably includes another repeating unit other than the repeating unit represented by the formula (I).

The polymer compound used in the present invention may further include a repeating unit represented by the formula (II):

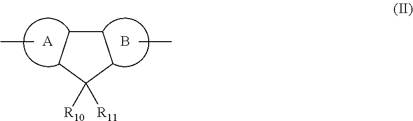

wherein a ring A and a ring B are the same or different and represent an aromatic ring, and R₁₀ and R₁₁ are the same or different, represent a hydrogen atom or a substituent, and may be linked with each other to form a cyclic structure.

When R₁₀ and R₁₁ are a substituent, examples of the substituents include alkyl groups such as a methyl group, an ethyl group, a butyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group and an eicosyl group; and aryl groups such as a phenyl group and a naphthyl group. R₁₀ and R₁₁ are preferably a hydrocarbon group such as alkyl groups and aryl groups, and more preferably alkyl groups. When R₁₀ and R₁₁ are a substituent, the substituent preferably has 12 or more carbon atoms.

Examples of the ring A and the ring B include aromatic hydrocarbon rings such as a benzene ring and a naphthalene ring, and aromatic heterocyclic rings such as thiophene. The ring A and the ring B are preferably composed of from a five-membered ring to a ten-membered ring, and are more preferably a benzene ring or a naphthalene ring.

The repeating unit represented by the formula (II) is preferably a repeating unit represented by the formula (II-1):

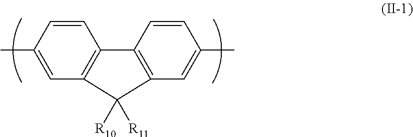

wherein R₁₀ and R₁₁ represent the same as those described above.

When the polymer compound used in the present invention has the repeating unit represented by the formula (II) in addition to the repeating unit represented by the formula (I), it is preferable that the proportion of the repeating unit represented by the formula (II) is the second highest after the proportion of the repeating unit represented by the formula (I) among all of the repeating units contained in the polymer compound, and it is more preferable that the repeating units in the polymer compound only has the repeating unit represented by the formula (I) and the repeating unit represented by the formula (II).

### <Method of Producing Polymer Compound>

A method of producing the polymer compound used in the present invention is not particularly limited, but a method in which a Suzuki coupling reaction is used is preferable in point of ease of synthesis of the polymer compound.

Examples of the methods of using the Suzuki coupling reaction include a production method comprising the step of reacting one or more compounds represented by the formula (100):

Q₁-E₁-Q₂ (100),

wherein E₁ represents the same group as one of the formula (II), and Q₁ and Q₂ are the same or different and represent a boronic acid residue or a borate residue, with one or more compounds represented by the formula (200):

T₁-E₂-T₂ (200),

wherein E₂ represents the groups as one of the formula (I), and T₁ and T₂ are the same or different and represent a halogen atom, an alkylsulfonate group, an arylsulfonate group or an arylalkylsulfonate group, in the presence of a palladium catalyst and a base.

In this case, it is required that a total of molar numbers of one or more compounds represented by the formula (200) to be used in the reaction exceeds a total of molar numbers of one or more compounds represented by the formula (100). When the total of molar numbers of one or more compounds represented by the formula (200) to be used in the reaction is taken as 1 mol, the total of molar numbers of one or more compounds represented by the formula (100) is preferably, 0.6 to 0.99 mol, and more preferably 0.7 to 0.95 mol.

Examples of the borate residue include groups represented by the following formula:

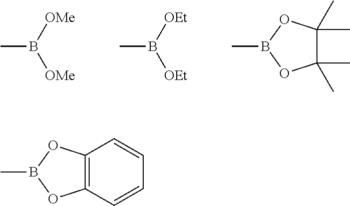

wherein Me represents a methyl group, and Et represents an ethyl group.

Examples of the halogen atoms in T¹ and T² in the formula (200) include a fluorine atom, a chlorine atom, a bromine atom, and an iodine atom. The bromine atom and the iodine atom are preferable and the bromine atom is more preferable in point of ease of synthesis of the polymer compound.

Examples of the alkylsulfonate groups in T¹ and T² in the formula (200) include a methanesulfonate group, an ethanesulfonate group, and a trifluoromethanesulfonate group. Examples of the arylsulfonate groups include a benzenesulfonate group and a p-toluenesulfonate group. Examples of the arylsulfonate groups include a benzylsulfonate group.

Specifically, as the catalyst, for example, palladium[tetrakis(triphenylphosphine)], palladium acetates or dichlorobis(triphenylphosphine)palladium(II) is used, and an inorganic base such as potassium carbonate, sodium carbonate, barium hydroxide or the like, an organic base such as triethylamine or the like, or an inorganic salt such as cesium fluoride or the like is added in an equivalent amount or more, preferably in 1 to 20 equivalent amount with respect to a monomer to react the resulting mixture. Examples of a solvent include N,N-dimethylformamide, toluene, dimethoxyethane, and tetrahydrofuran. The base is added as an aqueous solution and may be reacted in a two-phase system. When the base is reacted in a two-phase system, a phase-transfer catalyst such as quaternary ammonium salt may be added as required. Depending on a solvent, as a reaction temperature, a temperature of about 50 to 160° C. is suitably employed. A reactant may be heated to almost a boiling point of the solvent and may be refluxed. A reaction time is about 0.1 to 200 hours. In addition, the reaction is carried out under the condition, in which a catalyst is not deactivated, in an atmosphere of inert gas such as argon gas, nitrogen gas or the like.

Palladium Catalyst

Examples of the palladium catalyst to be used in a production method of the polymer compound used in the present invention include palladium[tetrakis(triphenylphosphine)], palladium acetates and dichlorobis(triphenylphosphine)palladium(II) including a Pd(0) catalyst and a Pd(II) catalyst, and dichlorobis(triphenylphosphine)palladium(II) and palladium acetates are preferable from the viewpoint of ease of a reaction (polymerization) operation and a reaction (polymerization) rate.

The additive amount of the palladium catalyst is not particularly limited as long as it is an effective amount as a catalyst, and it is usually 0.0001 to 0.5 mol, and preferably 0.0003 to 0.1 mol with respect to 1 mol of the compound represented by the formula (100).

Base

Examples of the base to be used in a production method of the polymer compound used in the present invention include inorganic bases, organic bases and inorganic salts. Examples of the inorganic bases include potassium carbonate, sodium carbonate, and barium hydroxide. Examples of the organic bases include triethylamine, and tributylamine. Examples of the inorganic salts include cesium fluoride.

The additive amount of the base is usually 0.5 to 100 mol, preferably 0.9 to 20 mol, and more preferably 1 to 10 mol with respect to 1 mol of the compound represented by the formula (100).

Other Components

When palladium acetates are used as the palladium catalyst, phosphorus compounds such as triphenylphosphine, tri(o-tolyl)phosphine and tri(o-methoxyphenyl)phosphine can be added as a ligand. In this case, the additive amount of the ligand is usually 0.5 to 100 mol, preferably 0.9 to 20 mol, and more preferably 1 to 10 mol with respect to 1 mol of the palladium catalyst.

In the production method of the polymer compound used in the present invention, the above-mentioned reaction is commonly carried out in a solvent. Examples of the solvent include N,N-dimethylformamide, toluene, dimethoxyethane, and tetrahydrofuran. Toluene and tetrahydrofuran are preferable from the viewpoint of the solubility of the polymer compounds used in the present invention. The base is added as an aqueous solution and may be reacted in a two-phase system. When an inorganic salt is used as the base, the inorganic salt is commonly added as an aqueous solution from the viewpoint of the solubility of the inorganic salt and is reacted in a two-phase system.

In addition, when the base is added as an aqueous solution and reacted in a two-phase system, a phase-transfer catalyst such as quaternary ammonium salt may be added as required.

Reaction Condition

Depending on the solvent, a temperature at which the reaction is carried out is usually 50 to 160° C., and preferably 60 to 120° C. from the viewpoint of increasing a molecular weight of the polymer compound. A reactant may be heated to almost a boiling point of the solvent and may be refluxed. Although a period of time, during which the reaction is carried out, (reaction time) may be a period of time in the case where the time when reaching a desired polymerization degree is taken as a reaction end point, but it is usually about 0.1 to 200 hours although. The reaction time of about 1 to 30 hours is efficient and preferable.

The reaction is carried out in a reaction system, in which a Pd (0) catalyst is not deactivated, in an atmosphere of inert gas such as an argon gas, a nitrogen gas or the like. For example, the reaction is carried out in a system which is adequately deaerated with an argon gas or a nitrogen gas. Specifically, after the inside of a polymerization vessel (reaction system) is adequately replaced and deaerated with a nitrogen gas, into the polymerization vessel, a compound represented by the formula (100), a compound represented by the formula (200) and dichlorobis(triphenylphosphine)palladium (II) are charged, and further the inside of the polymerization vessel is adequately replaced with a nitrogen gas and deaerated, and then a solvent which had been previously deaerated by being bubbled, for example, toluene was added, and then to the resulting solution, a base which had been previously deaerated by being bubbled with a nitrogen gas, for example, an aqueous solution of sodium carbonate is added dropwise. Thereafter, the resulting solution is heated and the temperature is elevated, for example, at a reflux temperature for 8 hours while maintaining an inert atmosphere.

A number average molecular weight on the polystyrene equivalent basis of the polymer compound used in the present invention is 1×10³ to 1×10⁸, and preferably 2×10³ to 1×10⁷. When the number average molecular weight on the polystyrene equivalent basis is 1×10³ or more, a tough thin film can be easily attained. On the other hand, when the number average molecular weight is 10⁸ or less, the solubility of the polymer compound is high and it is easy to prepare a thin film. A weight average molecular weight on the polystyrene equivalent basis is usually 1.1×10³ to 1.1×10⁸, and preferably 2.2×10³ to 1.1×10⁷.

A terminal group of the polymer compound used in the present invention may be protected by a stable group since if a polymerizable active group remains at the end group, characteristics and life of a resulting element can be deteriorated when the polymer compound is used for preparation of the element. The terminal group having a conjugated bond continuously connected to a conjugated structure of a main chain is preferable, and for example, a structure, in which the end group is coupled with an aryl group or a heterocyclic group with a vinylene group interposed therebetween, may be employed. Specifically, the substituents described as [Chem 10] in JP Hei-9-45478A are shown.

### <Photoelectric Conversion Element>

The photoelectric conversion element of the present invention comprises one or more photoactive layers containing the polymer compound of the present invention between a pair of electrodes, at least one of which is transparent or translucent.

The photoelectric conversion element of the present invention preferably comprises a pair of electrodes, at least one of which is transparent or translucent, and a photoactive layer formed from an organic composition of a p-type organic semiconductor and an n-type organic semiconductor. An operating mechanism of the photoelectric conversion element of this form will be described. Light energy passing through the transparent or translucent electrode is absorbed by an electron accepting compound (n-type organic semiconductor) such as fullerene derivatives and/or an electron donating compound (p-type organic semiconductor) such as a conjugated polymer compound to produce an exciton in which an electron and a hole are combined into one. When the produced exciton moves and reaches a hetero junction interface where the electron accepting compound and the electron donating compound exist next to each other, the exciton is separated into the electron and the hole due to a difference between HOMO (highest occupied molecular orbital) energy and LUMO (lowest unoccupied molecular orbital) energy at the interface to generate charges (electron and hole) which can independently move. The generated charges are respectively travel to electrodes, and thereby the charges can be externally drawn out as electric energy (electric current).

The photoelectric conversion element of the present invention is generally formed on a substrate. It is preferred that the substrate is not deformed when an electrode is formed and an organic material layer is formed on the substrate. Examples of the materials of the substrate include glass, plastic, polymer film, and silicon. When the substrate is an opaque substrate, an opposite electrode (that is, an electrode on a side far from the substrate) is preferably a transparent or translucent electrode.

Examples of materials of the transparent or translucent electrode include conductive metal oxide films, and translucent metal thin films. Specifically, films (NESA, etc.) prepared by use of conductive materials comprising indium oxide, zinc oxide, tin oxide and composites thereof, for example, indium tin oxide (ITO) and indium zinc oxide (IZO), or gold, platinum, silver or copper is used, and ITO, indium zinc oxide and tin oxide are preferable. Examples of a method for preparing the electrode include a vacuum deposition method, a sputtering method, an ion plating method, and a plating method. As an electrode material, organic transparent conductive films such as polyaniline and derivatives thereof, polythiophene and derivatives thereof and the like may be used. Moreover, as the electrode material, metals or conductive polymers can be further used. A material of one electrode of the pair of electrodes is preferably a material having a small work function. As such materials, metals such as lithium, sodium, potassium, rubidium, cesium, magnesium, calcium, strontium, barium, aluminum, scandium, vanadium, zinc, yttrium, indium, cerium, samarium, europium, terbium or ytterbium, or alloys of two or more thereof; alloys of one or more of the above-mentioned metals and one or more of gold, silver, platinum, copper, manganese, titanium, cobalt, nickel, tungsten and tin; or graphite or graphite interlayer compounds are used. Examples of the alloys include magnesium-silver alloy, magnesium-indium alloy, magnesium-aluminum alloy, indium-silver alloy, lithium-aluminum alloy, lithium-magnesium alloy, lithium-indium alloy, and calcium-aluminum alloy.

An additional intermediate layer other than the photoactive layer may be used as a means of improving photoelectric conversion efficiency. Examples of a material used as an intermediate layer include alkali metal such as lithium fluoride and the like, and halide and oxide of alkaline earth metals. Further, examples of a material of the intermediate layer include fine particles of inorganic semiconductor such as titanium oxide and PEDOT (poly-3,4-ethylenedioxythiophene).

### <Photoactive Layer>

The photoactive layer may contain one polymer compound of the present invention alone, or may contain the polymer compounds in combination of two or more species. In order to enhance a hole transporting property of the photoactive layer, a low molecular compound and/or a polymer compound other than the polymer compound of the present invention can be mixed in the photoactive layer as the electron donating compound and/or the electron accepting compound.

Examples of the electron donating compounds include, in addition to the polymer compounds of the present invention, pyrazoline derivatives, arylamine derivatives, stilbene derivatives, triphenyldiamine derivatives, oligothiophene and derivatives thereof, polyvinylcarbazole and derivatives thereof, polysilane and derivatives thereof, polysiloxane derivatives having aromatic amine on the side chain or main chain, polyaniline and derivatives thereof, polythiophene and derivatives thereof, polypyrrole and derivatives thereof, polyphenylenevinylene and derivatives thereof, and polythienylenevinylene and derivatives thereof.

Examples of the electron accepting compound include, in addition to the polymer compounds of the present invention, oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complex of 8-hydroxyquinoline and derivatives thereof, polyquinoline and derivatives thereof, polyquinoxaline and derivatives thereof, polyfluorene and derivatives thereof, fullerenes such as C₆₀ and the like and derivatives thereof, and phenanthrene derivatives such as bathocuproin, and particularly, fullerenes and derivatives thereof are preferable.

The electron donating compound and the electron accepting compound are determined based on a relative level of the energy level of these compounds.

The photoactive layer contained in the photoelectric conversion element of the present invention contains the electron donating compound and the electron accepting compound. One of the electron donating compound and the electron accepting compound is a polymer compound having a repeating unit represented by the formula (I), and the other of the electron donating compound and the electron accepting compound is a compound which is used in conjunction with the polymer compound having a repeating unit represented by the formula (I) in the photoactive layer. When levels of HOMO energy and LUMO energy of the polymer compound having a repeating unit represented by the formula (I) are shallower than levels of HOMO energy and LUMO energy of the other compound used in combination, the polymer compound having a repeating unit represented by the formula (I) acts as an electron donating compound.

One aspect of the photoelectric conversion element of the present invention uses the polymer compound having a repeating unit represented by the formula (I) as an electron donating compound. As the electron accepting compounds in the present aspect, fullerenes, fullerene derivatives, carbon nanotubes, and carbon nanotube derivatives are preferable.

Examples of the fullerenes include C60 fullerene, C70 fullerene, C76 fullerene, C78 fullerene, and C84 fullerene.

Examples of the fullerene derivatives include [6,6]-phenyl-C₆₁-butyric acid methyl ester (C60 PCBM), [6, 6]-phenyl-C₇₁-butyric acid methyl ester (C70 PCBM), [6]-phenyl-C₈₅-butyric acid methyl ester (C84 PCBM), and [6,6]-thienyl-C₆₁-butyric acid methyl ester (C60 PCBM).

When the fullerene derivative is used as an electron accepting compound, a rate of the fullerene derivative is preferably 10 to 1000 parts by weight, and more preferably 20 to 500 parts by weight with respect to 100 parts by weight of the electron donating compound.

When levels of HOMO energy and LUMO energy of the polymer compound having a repeating unit represented by the formula (I) are lower than levels of HOMO energy and LUMO energy of the other compound used in combination, the polymer compound having a repeating unit represented by the formula (I) acts as an electron accepting compound.

One aspect of the photoelectric conversion element of the present invention uses the polymer compound having a repeating unit represented by the formula (I) as an electron accepting compound. In this case, as the electron donating compounds, the polymer compound having a thiophene structure is preferable. The polymer compound having a thiophene structure is more preferably a polythiophene homopolymer. The polythiophene polymer is a polymer formed by combining a plurality of constituent units selected from thiophenediyl groups and substituted thiophenediyl groups. As the thiophenediyl groups, a thiophene-2,5-diyl group is preferable, and as the substituted thiophenediyl groups, an alkylthiophene-2,5-diyl group is preferable.

Examples of the polythiophene homopolymers include poly(3-hexylthiophene-2,5-diyl) (P3HT), poly(3-octylthiophene-2,5-diyl), poly(3-dodecylthiophene-2,5-diyl), and poly(3-octadecylthiophene-2,5-diyl). Among the polythiophene homopolymers, polythiophene homopolymers replaced with an alkyl group having 6 to 30 carbon atoms are preferable.

The thickness of the photoactive layer is usually 1 nm to 100 μm, preferably 2 nm to 1000 nm, more preferably 5 nm to 500 nm, and furthermore preferably 20 nm to 200 nm.

### <Method of Fabricating Photoactive Layer>

As a method of fabricating a photoactive layer, any method may be employed to fabricate the photoactive layer, and examples of the methods include a method of forming a film from a solution containing a polymer compound, and a method of forming a film by a vacuum deposition method.

A solvent to be used for forming a film from a solution is not particularly limited as long as the polymer compound (polymer) of the present invention is dissolved in the solvent. Examples of the solvent include unsaturated hydrocarbon solvents such as toluene, xylene, mesitylene, tetralin, decalin, bicyclohexyl, n-butylbenzene, sec-butylbenzene and tert-butylbenzene; halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane and bromocyclohexane; halogenated unsaturated hydrocarbon solvents such as chlorobenzene, dichlorobenzene and trichlorobenzene; and ether solvents such as tetrahydrofuran and tetrahydropyran. The polymer compound (polymer) of the present invention can be generally dissolved in the above solvent in an amount 0.1% by weight or more.

For forming a film, application methods, such as a spin coating method, a casting method, a microgravure coating method, a gravure coating method, a bar coating method, a roll coating method, a wire bar coating method, a dip coating method, a spray coating method, a screen printing method, a gravure printing method, a flexo printing method, an offset printing method, an ink jet printing method, a dispenser printing method, a nozzle coating method and a capillary coating method, can be used, and the spin coating method, the flexo printing method, the gravure printing method, the ink jet printing method, and the dispenser printing method are preferably used.

### <Application of Element>

The photoelectric conversion element of the present invention can be operated as an organic thin film solar cell since a photovoltaic power is generated between electrodes by being irradiated from a transparent or translucent electrode with light such as solar light. The photoelectric conversion element of the present invention can also be used as an organic thin film solar cell module by integrating a plurality of organic thin film solar cells.

The photoelectric conversion element of the present invention can be operated as an organic optical sensor since a photocurrent flows by being irradiated from a transparent or translucent electrode with light in a state of applying or not applying a voltage between the electrodes. The photoelectric conversion element of the present invention can also be used as an organic image sensor by integrating a plurality of organic optical sensors.

### EXAMPLES

Hereinafter, examples will be described in order to explain the present invention in more detail, but the present invention is not limited to these examples.

### Synthesis Example 1

### Production of Polymer A

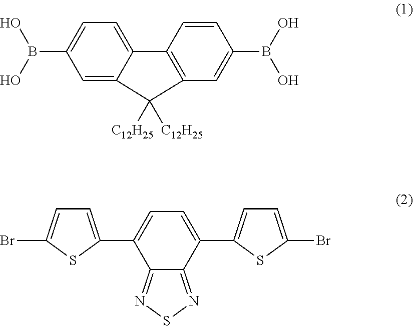

0.945 g (1.60 mmol) of the monomer (1), 0.918 g (2.00 mmol) of the monomer (2), and 25 mg of tetrakis(triphenylphosphine)palladium(0) were charged into a reaction vessel, and the inside of the reaction vessel was adequately replaced with an argon gas. To the reaction vessel, 50 g of toluene, which had been previously deaerated by being bubbled with an argon gas, was added. The resulting solution was stirred at 100° C. for about 10 minutes. Next, to the resulting solution, 5 ml of a tetraethylammonium hydroxide solution (20% aqueous solution), which had been previously deaerated by being bubbled with an argon gas, was added dropwise, and then the mixed solution was refluxed for 3.5 hours. Next, to the resulting reaction solution, 0.55 g of phenylboric acid was added, and the resulting mixture was refluxed for 8.5 hours. A reaction was performed in an argon gas atmosphere.

After the completion of the reaction, the reactant solution was cooled to almost room temperature and then left to stand to separate a toluene layer, and the toluene layer was obtained. Then, the obtained toluene layer was poured into methanol to be reprecipitated, and a produced precipitate was collected. The precipitate was dried under a reduced pressure and then dissolved in chloroform. Next, the obtained chloroform solution was filtered to remove insoluble substances and then passed through an alumina column to be purified. Then, the resulting chloroform solution was concentrated under a reduced pressure, poured into methanol to be reprecipitated, and a produced precipitate was collected. The precipitate was washed with methanol and dried under a reduced pressure to obtain 0.93 g of a polymer. Hereinafter, this polymer is referred to as a polymer A. A weight average molecular weight on the polystyrene equivalent basis of the polymer A was 2.0×10⁴ and a number average molecular weight on the polystyrene equivalent basis was 4.7×10³.

A ratio of a repeating unit represented by the formula (2′), which was calculated from a charging ratio, among all of the repeating units of the polymer A was 55.6%.

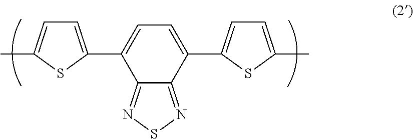

### Synthesis Example 2

### Production of Polymer B

1.063 g (1.80 mmol) of the monomer (1), 0.756 g (1.65 mmol) of the monomer (2), and 25 mg of tetrakis(triphenylphosphine)palladium(0) were charged into a reaction vessel, and the inside of the reaction vessel was adequately replaced with an argon gas. To the reaction vessel, 50 g of toluene, which had been previously deaerated by being bubbled with an argon gas, was added. The resulting solution was stirred at 100° C. for about 10 minutes. Next, to the resulting solution, 5 ml of a tetraethylammonium hydroxide solution (20% aqueous solution), which had been previously deaerated by being bubbled with an argon gas, was added dropwise, and then the mixed solution was refluxed for 2.5 hours. To the resulting reaction solution, 0.25 g of bromobenzene was added, and the resulting mixture was refluxed for 1 hour. Then, 0.30 g of phenylboric acid was added to the resulting reaction solution, and the resulting mixture was refluxed for 8.5 hours. A reaction was performed in an argon gas atmosphere.

After the completion of the reaction, the reactant solution was cooled to almost room temperature and then left to stand to separate a toluene layer, and the toluene layer was obtained. Then, the obtained toluene layer was poured into methanol to be reprecipitated, and a produced precipitate was collected. The precipitate was dried under a reduced pressure and then dissolved in chloroform. Next, the obtained chloroform solution was filtered to remove insoluble substances and then passed through an alumina column to be purified. Then, the resulting chloroform solution was concentrated under a reduced pressure, poured into methanol to be reprecipitated, and a produced precipitate was collected. The precipitate was washed with methanol and dried under a reduced pressure to obtain 1.0 g of a polymer. Hereinafter, this polymer is referred to as a polymer B. A weight average molecular weight on the polystyrene equivalent basis of the polymer B was 6.5×10⁴ and a number average molecular weight on the polystyrene equivalent basis was 1.4×10³.

A ratio of a repeating unit represented by the formula (2′), which was calculated from a charging ratio, among all of the repeating units of the polymer B was 47.8%.

### Synthesis Example 3

### Production of Polymer C

14.172 g (24.0 mmol) of the monomer (1), 13.746 g (30.0 mmol) of the monomer (2), 6.75 g of methyltrioctylammonium chloride (trade name: aliquat 336, manufactured by Aldrich Chemical Company, Inc., CH₃N[(CH₂)₇CH₃]₃Cl, density 0.884 g/ml at 25° C., trademark of Henkel Corporation), 62.6 mg of palladium(II) acetate, and 338 mg of tris(2-methoxyphenyl)phosphine were charged into a reaction vessel, and the inside of the reaction vessel was adequately replaced with an argon gas. To the reaction vessel, 600 g of toluene, which had been previously deaerated by being bubbled with an argon gas, was added. Next, to the resulting solution, 150 ml of a 16.7 weight % aqueous solution of sodium carbonate, which had been previously deaerated by being bubbled with an argon gas, was added dropwise, and then the mixed solution was heated to a temperature at which the solvent was refluxed, and refluxed for 8 hours. A reaction was performed in an argon gas atmosphere.

Then, the resulting reaction solution was cooled, and to this, a mixed solution of 3.0 g of phenylboric acid and 7.0 ml of tetrahydrofuran was added, and the resulting mixture was refluxed for 9 hours. A reaction was performed in an argon gas atmosphere.

After the completion of the reaction, the resulting reactant solution was cooled and then left to stand to separate a toluene layer, and the toluene layer was obtained. Next, the obtained toluene layer was poured into methanol to be reprecipitated, and a produced precipitate was collected. The precipitate was dried under a reduced pressure and then dissolved in chloroform. Next, the obtained chloroform solution was filtered to remove insoluble substances and then passed through an alumina column to be purified. Then, the resulting chloroform solution was concentrated under a reduced pressure, poured into methanol to be reprecipitated, and a produced precipitate was collected. The precipitate was washed with methanol and dried under a reduced pressure to obtain 14.8 g of a polymer. Hereinafter, this polymer is referred to as a polymer C. A weight average molecular weight on the polystyrene equivalent basis of the polymer C was 2.8×10⁴ and a number average molecular weight on the polystyrene equivalent basis was 8.3×10³.

A ratio of a repeating unit represented by the formula (2′), which was calculated from a charging ratio, among all of the repeating units of the polymer C was 55.6%.

### Synthesis Example 4

### Production of Polymer D

0.473 g (0.801 mmol) of the monomer (1), 0.450 g (0.983 mmol) of the monomer (2), 0.33 g of methyltrioctylammonium chloride (trade name: aliquat 336, manufactured by Aldrich Chemical Company, Inc., CH₃N [(CH₂)₇CH₃]₃C1, density 0.884 g/ml at 25° C., trademark of Henkel Corporation), 2.0 mg of palladium (II) acetate, 23 mg of tris (2-methoxyphenyl)phosphine, and 49 mg of phenylboric acid were charged into a reaction vessel, and the inside of the reaction vessel was adequately replaced with an argon gas. To the reaction vessel, 40 ml of toluene, which had been previously deaerated by being bubbled with an argon gas, was added. Next, to the resulting solution, 5 ml of a 16.7 weight % aqueous solution of sodium carbonate, which had been previously deaerated by being bubbled with an argon gas, was added dropwise, and then the mixed solution was heated to a temperature at which the solvent was refluxed, and refluxed for 17 hours. A reaction was performed in an argon gas atmosphere.

After the completion of the reaction, the resulting reactant solution was cooled and then left to stand to separate a toluene layer, and the toluene layer was obtained. Next, the obtained toluene layer was poured into methanol to be reprecipitated, and a produced precipitate was collected. The precipitate was dried under a reduced pressure and then dissolved in chloroform. Next, the obtained chloroform solution was filtered to remove insoluble substances and then passed through an alumina column to be purified. Then, the resulting chloroform solution was concentrated under a reduced pressure, poured into methanol to be reprecipitated, and a produced precipitate was collected. The precipitate was washed with methanol and dried under a reduced pressure to obtain 0.34 g of a polymer. Hereinafter, this polymer is referred to as a polymer D. A weight average molecular weight on the polystyrene equivalent basis of the polymer D was 1.3×10⁴ and a number average molecular weight on the polystyrene equivalent basis was 6.6×10³.

A ratio of a repeating unit represented by the formula (2′), which was calculated from a charging ratio, among all of the repeating units of the polymer D was 55.1%.

### Synthesis Example 5

### Production of Polymer E

0.360 g (0.610 mmol) of the monomer (1), 0.458 g (1.00 mmol) of the monomer (2), 0.37 g of methyltrioctylammonium chloride (trade name: aliquat 336, manufactured by Aldrich Chemical Company, Inc., CH₃N [(CH₂)₇CH₃]₃Cl, density 0.884 g/ml at 25° C., trademark of Henkel Corporation), 2.0 mg of palladium (II) acetate, 10.8 mg of tris(2-methoxyphenyl)phosphine, and 98 mg of phenylboric acid were charged into a reaction vessel, and the inside of the reaction vessel was adequately replaced with an argon gas. To the reaction vessel, 40 ml of toluene, which had been previously deaerated by being bubbled with an argon gas, was added. Next, to the resulting solution, 5 ml of a 16.7 weight % aqueous solution of sodium carbonate, which had been previously deaerated by being bubbled with an argon gas, was added dropwise, and then the mixed solution was heated to a temperature at which the solvent was refluxed, and refluxed for 17 hours. A reaction was performed in an argon gas atmosphere.

After the completion of the reaction, the resulting reactant solution was cooled and then left to stand to separate a toluene layer, and the toluene layer was obtained. Next, the obtained toluene layer was poured into methanol to be reprecipitated, and a produced precipitate was collected. The precipitate was dried under a reduced pressure and then dissolved in chloroform. Next, the obtained chloroform solution was filtered to remove insoluble substances and then passed through an alumina column to be purified. Then, the resulting chloroform solution was concentrated under a reduced pressure, poured into methanol to be reprecipitated, and a produced precipitate was collected. The precipitate was washed with methanol and dried under a reduced pressure to obtain 0.27 g of a polymer. Hereinafter, this polymer is referred to as a polymer E. A weight average molecular weight on the polystyrene equivalent basis of the polymer E was 6.0×10³ and a number average molecular weight on the polystyrene equivalent basis was 2.5×10³.

A ratio of a repeating unit represented by the formula (2′), which was calculated from a charging ratio, among all of the repeating units of the polymer E was 62.10.

### Example 1

### Preparation and Evaluation of Organic Thin Film Solar Cell

A glass substrate provided with an ITO film of 150 nm in thickness by a sputtering method was surface treated by an ozone UV treatment. Next, an ortho-dichlorobenzene solution (a weight ratio of polymer A to PCBM is 1/3) containing the polymer A of a polymer compound and C60 PCBM (phenyl-C₆₁-butyric acid methyl ester, manufactured by Frontier Carbon Corp.) of a fullerene derivative was used and the solution was applied by spin coating to prepare a photoactive layer (film thickness about 100 nm). Then, lithium fluoride was deposited in a thickness of 4 nm by a vacuum vapor deposition machine, and then aluminum was deposited in a thickness of 100 nm. The shape of the resulting organic thin film solar cell was a square having a size of 2 mm×2 mm. The obtained organic thin film solar cell was irradiated with a certain amount of light using a solar simulator (trade name OTENTO-SUNII manufactured by BUNKOUKEIKI Co., Ltd.: AM 1.5G Filter, irradiance 100 mW/cm²), and a current and a voltage generated were measured to determine photoelectric conversion efficiency, a short-circuit current density, an open circuit voltage and a fill factor. The short-circuit current density (Jsc) was 5.34 mA/cm², the open circuit voltage (Voc) was 0.825 V, the fill factor (ff) was 0.44, and the photoelectric conversion efficiency (η) was 1.93%.

### Comparative Example 1

### Preparation and Evaluation of Organic Thin Film Solar Cell

An organic thin film solar cell was prepared in the same manner as in Example 1 except for using the polymer B in place of the polymer A as a polymer compound and evaluated. Consequently, Jsc was 3.17 mA/cm², Voc was 0.800V, ff was 0.402, and the photoelectric conversion efficiency (η) was 1.01%.

### Example 2

### Preparation and Evaluation of Organic Thin Film Solar Cell

An organic thin film solar cell was prepared in the same manner as in Example 1 except for using the polymer C in place of the polymer A as a polymer compound and evaluated. Consequently, Jsc was 5.91 mA/cm², Voc was 0.947 V, ff was 0.495, and the photoelectric conversion efficiency (η) was 2.77%.

### Example 3

### Preparation and Evaluation of Organic Thin Film Solar Cell

An organic thin film solar cell was prepared in the same manner as in Example 1 except for using the polymer D in place of the polymer A as a polymer compound and evaluated. Consequently, Jsc was 5.79 mA/cm², Voc was 0.971 V, ff was 0.489, and the photoelectric conversion efficiency (η) was 2.75%.

### Example 4

### Preparation and Evaluation of Organic Thin Film Solar Cell

An organic thin film solar cell was prepared in the same manner as in Example 1 except for using the polymer E in place of the polymer A as a polymer compound and evaluated. Consequently, Jsc was 5.38 mA/cm², Voc was 0.957 V, ff was 0.389, and the photoelectric conversion efficiency (η) was 2.00%.

### Example 5

### Preparation and Evaluation of Organic Thin Film Solar Cell

An organic thin film solar cell was prepared in the same manner as in Example 1 except for using an ortho-dichlorobenzene solution (a weight ratio of polymer C to PCBM is 1/3) containing the polymer C in place of the polymer A as a polymer compound and C70 PCBM (phenyl-C₇₁-butyric acid methyl ester, manufactured by Frontier Carbon Corp.) in place of the C60 PCBM, and evaluated. Consequently, Jsc was 8.00 mA/cm², Voc was 0.998 V, ff was 0.486, and the photoelectric conversion efficiency (η) was 3.88%.

### Example 6

### Preparation and Evaluation of Organic Thin Film Solar Cell

An organic thin film solar cell was prepared in the same manner as in Example 1 except for using an ortho-dichlorobenzene solution (a weight ratio of P3HT to polymer C is 1/1) containing poly(3-hexylthiophene-2,5-diyl) (P3HT) (REGIOREGULAR, manufactured by Merck Ltd., trade name lisicon SP001) in place of the polymer A as a polymer compound and the polymer C in place of the C60 PCBM, and evaluated. Consequently, Jsc was 1.27 mA/cm², Voc was 1.06 V, ff was 0.33, and the photoelectric conversion efficiency (η) was 0.44%.

### Comparative Example 2

### Preparation and Evaluation of Organic Thin Film Solar Cell

An organic thin film solar cell was prepared in the same manner as in Example 1 except for using an ortho-dichlorobenzene solution (a weight ratio of P3HT to polymer B is 1/1) containing P3HT in place of the polymer A as a polymer compound and the polymer B in place of the C60 PCBM, and evaluated. Consequently, Jsc was 0.54 mA/cm², Voc was 1.07 V, ff was 0.29, and the photoelectric conversion efficiency (II) was 0.17%.

### INDUSTRIAL APPLICABILITY

The photoelectric conversion element of the present invention is extremely industrially useful since it has high photoelectric conversion efficiency.

1. A photoelectric conversion element comprising a pair of electrodes, at least one of which is transparent or translucent, and a photoactive layer provided between the electrodes, wherein the photoactive layer contains an electron donating compound and an electron accepting compound, and the electron donating compound or the electron accepting compound is a polymer compound having a repeating unit represented by the following formula (I), and the proportion of the repeating unit represented by the formula (I) is the highest among all of the repeating units contained in the polymer compound: 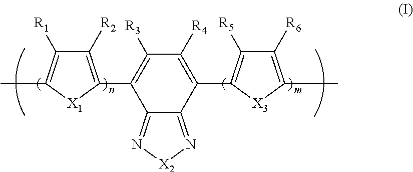
wherein R₁, R₂, R₃, R₄, R₅ and R₆ are the same or different, represent a hydrogen atom or a substituent, and may be linked with one another to form a cyclic structure; X₁, X₂ and X₃ are the same or different and represent a sulfur atom, an oxygen atom, a selenium atom, —N(R₇)— or —CR₈═CR₉—; R₇, R₈, and R₉ are the same or different and represent a hydrogen atom or a substituent; and n and m are the same or different and represent an integer of 0 to 5; and when a plurality of R₁s, R₂s, R₅s, R₆s, X₁s or X₂s respectively exist, they may be the same or different.

2. The photoelectric conversion element according to claim 1, wherein n and m are an integer of 1 to 3.

3. The photoelectric conversion element according to claim 1, wherein X₁, X₂ and X₃ are a sulfur atom, respectively.

4. The photoelectric conversion element according to claim 1, wherein an amount of the repeating unit represented by the formula (I) is more than 50% of a total of all repeating units in the polymer compound.

5. The photoelectric conversion element according to claim 4, wherein an amount of the repeating unit represented by the formula (I) is 52% or more of a total of all repeating units in the polymer compound.

6. The photoelectric conversion element according to claim 1, wherein an amount of the repeating unit represented by the formula (I) is less than 100% of a total of all repeating units in the polymer compound.

7. The photoelectric conversion element according to claim 6, wherein an amount of the repeating unit represented by the formula (I) is 98% or less of a total of all repeating units in the polymer compound.

8. The photoelectric conversion element according to claim 1, wherein the polymer compound further includes a repeating unit represented by the formula (II): 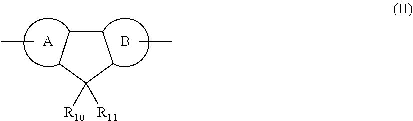
wherein a ring A and a ring B are the same or different and represent an aromatic ring, and R₁₀ and R₁₁ are the same or different, and represent a hydrogen atom or a substituent, and may be linked with each other to form a cyclic structure.

9. The photoelectric conversion element according to claim 8, wherein the proportion of the repeating unit represented by the formula (II) is the second highest after the proportion of the repeating unit represented by the formula (I) among all of the repeating units contained in the polymer compound.

10. The photoelectric conversion element according to claim 8, wherein the repeating units in the polymer compound are only the repeating unit represented by the formula (I) and the repeating unit represented by the formula (II).

11. The photoelectric conversion element according to claim 1, wherein R₁, R₂, R₅ and R₆ are a hydrogen atom.

12. The photoelectric conversion element according to claim 1, wherein R₃ and R₄ are a hydrogen atom.

13. The photoelectric conversion element according to claim 1, wherein R₁₀ and R₁₁ are a hydrocarbon group.

14. The photoelectric conversion element according to claim 13, wherein R₁₀ and R₁₁ are an alkyl group.

15. The photoelectric conversion element according to claim 13, wherein R₁₀ has 12 or more carbon atoms and R₁₁ has 12 or more carbon atoms.

16. The photoelectric conversion element according to claim 8, wherein the ring A and the ring B are composed of from a five-membered ring to a ten-membered ring.

17. The photoelectric conversion element according to claim 16, wherein the ring A and the ring B are a benzene ring or a naphthalene ring.

18. The photoelectric conversion element according to claim 1, wherein an electron donating compound is the polymer compound including repeating unit represented by the formula (I) and an electron accepting compound is a polymer compound having a thiophene structure.

19. The photoelectric conversion element according to claim 1, wherein an electron accepting compound is the polymer compound having a repeating unit represented by the formula (I) and an electron donating compound is a polymer compound having a thiophene structure.

20. The photoelectric conversion element according to claim 18, wherein the polymer compound having a thiophene structure is a polythiophene homopolymer.

21. An image sensor comprising the photoelectric conversion element according to claim 1.

22. A polymer compound including repeating units represented by the formula (I), and the proportion of the repeating unit represented by the formula (I) is the highest among all of the repeating units contained in the polymer compound: 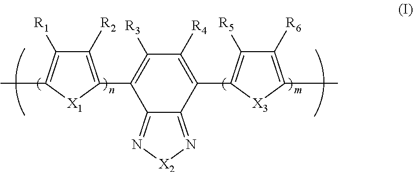
wherein R₁, R₂, R₃, R₄, R₅ and R₆ are the same or different and represent a hydrogen atom or a substituent, and may be linked with one another to form a cyclic structure; X₁, X₂ and X₃ are the same or different and represent a sulfur atom, an oxygen atom, a selenium atom, —N(R₇)— or —CR₈═CR₉—; R₇, R₈, and R₉ are the same or different and represent a hydrogen atom or a substituent; and n and m are the same or different and represent an integer of 0 to 5; and when a plurality of R₁s, R₂s, R₅s, R₆s, X₁s or X₃s respectively exist, they may be the same or different.

23. The polymer compound according to claim 22, wherein n and m are an integer of 1 to 3.

24. The polymer compound according to claim 22, wherein X₁, X₂ and X₃ are a sulfur atom, respectively.

25. The polymer compound according to claim 22, wherein an amount of the repeating unit represented by the formula (I) is more than 50% of a total of all repeating units in the polymer compound.

26. The polymer compound according to claim 25, wherein an amount of the repeating unit represented by the formula (I) is 52% or more of a total of all repeating units in the polymer compound.

27. The polymer compound according to claim 22, wherein an amount of the repeating unit represented by the formula (I) is less than 100% of a total of all repeating units in the polymer compound.

28. The polymer compound according to claim 27, wherein an amount of the repeating unit represented by the formula (I) is 98% or less of a total of all repeating units in the polymer compound.

29. The polymer compound according to claim 22, further including a repeating unit represented by the formula (II): 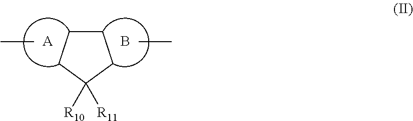
wherein a ring A and a ring B are the same or different and represent an aromatic ring; and R₁₀ and R₁₁ are the same or different and represent a hydrogen atom or a substituent, and may be linked with each other to form a cyclic structure.

30. The polymer compound according to claim 29, wherein the proportion of the repeating unit represented by the formula (II) is the second highest after the proportion of the repeating unit represented by the formula (I) among all of the repeating units contained in the polymer compound.

31. The polymer compound according to claim 29, wherein the repeating units in the polymer compound are only the repeating unit represented by the formula (I) and the repeating unit represented by the formula (II).

32. The polymer compound according to claim 22, wherein R₁, R₂, R₅ and R₆ are a hydrogen atom.

33. The polymer compound according to claim 22, wherein R₃ and R₄ are a hydrogen atom.

34. The polymer compound according to claim 29, wherein R₁₀ and R₁₁ are a hydrocarbon group.

35. The polymer compound according to claim 34, wherein R₁₀ and R₁₁ are an alkyl group.

36. The polymer compound according to claim 34, wherein R₁₀ has 12 or more carbon atoms and R₁₁ has 12 or more carbon atoms.

37. The polymer compound according to claim 29, wherein the ring A and the ring B are composed of from a five-membered ring to a ten-membered ring.

38. The polymer compound according to claim 37, wherein the ring A and the ring B are a benzene ring or a naphthalene ring.
